(19) United States
(12) Patent Application Publication
(10) Pub. No.: US 2024/0053674 A1
(43) Pub. Date: Feb. 15, 2024

(54) PHOTOMASK STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: CHUN-LANG CHEN, Tainan County (TW); SHIH-HAO YANG, Tainan City (TW); CHIH-CHIANG TU, Taoyuan (TW)

(21) Appl. No.: 17/818,368

(22) Filed: Aug. 9, 2022

(51) Int. Cl. G03F 1/48; H01L 21/033

(52) U.S. Cl. CPC G03F 1/48; H01L 21/0332

(57) ABSTRACT

A method for manufacturing a semiconductor structure is provided. The method may include several operations. A substrate is provided, received or formed. A multilayer structure is formed over the substrate, wherein the multilayer structure includes a plurality of silicon layers and a plurality of molybdenum layers alternately arranged with the plurality of silicon layers. A nitride layer and an oxide layer are formed over the multilayer structure, wherein a total thickness of the nitride layer and a topmost silicon layer is substantially equal to a thickness of each of all other silicon layers of the plurality of silicon layers. A patterned layer is formed over the nitride layer. A semiconductor structure thereof is also provided.

### BACKGROUND

In advanced semiconductor technologies, continuing reduction in device size and increasingly complex circuit arrangements have made design and fabrication of integrated circuits (ICs) more challenging and costly. To pursue better device performance with smaller footprint and less power, advanced lithography technologies, e.g., extreme ultraviolet (EUV) lithography, have been investigated as approaches to manufacturing semiconductor devices with a relatively small line width, e.g., 30 nm or less. EUV lithography employs a photomask to control irradiation of a substrate by EUV radiation so as to form a pattern on the substrate.

While existing lithography techniques have improved, they still fail to meet requirements in many aspects. For example, degradation of photomask materials has raised several issues.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, dimensions of the various features may be arbitrarily increased or reduced for clarity of discussion.

FIGS. 1 to 15 are schematic cross-sectional diagrams of a photomask structure at different stages of a manufacturing method in accordance with some embodiments of the disclosure.

FIGS. 16 to 17 are schematic cross-sectional diagrams of a photomask structure in accordance with some embodiments of the disclosure.

FIG. 18 is a flow diagram of a method of manufacturing a semiconductor structure in accordance with some embodiments of the disclosure.

FIG. 19 is a flow diagram of a method of manufacturing a semiconductor structure in accordance with some embodiments of the disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of times, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

An extreme ultraviolet (EUV) photomask is typically a reflective mask that includes circuit patterns and transfers patterned EUV radiation onto a wafer through reflection of incident EUV radiation during a photolithography operation. A layout of the EUV photomask includes an imaging region in which the circuit pattern is disposed. The EUV photomask at least includes a light-absorption layer over a light-reflective layer, in which the light-absorption layer is patterned to form the circuit pattern thereon. The EUV photomask generally includes a capping layer between the light-absorption layer and the light-reflective layer. The patterned EUV light is reflected from the light-reflective layer, through the capping layer and the patterned light-absorption layer, and radiated onto the wafer. A lithography performance of the EUV photomask is sensitive to refractive index of materials of the EUV photomask. Many reasons may result in changing in refractive index of the materials of the EUV photomask, and one of them is change in materials. Research has found that degradation or oxidation of reflective materials of an EUV photomask may occur during repeated exposure to EUV light.

The present disclosure provides a photomask and a method of manufacturing the photomask. In the proposed photomask, an anti-oxidation layer is formed on one or more layers of the photomask and serves to reduce or eliminate effects of oxidation of the layers of the photomask. As a result, a service life and operation cycles of the photomask are improved.

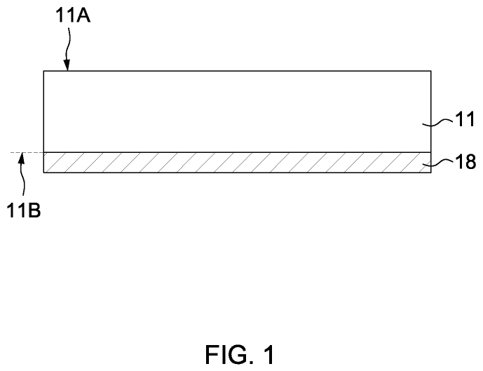

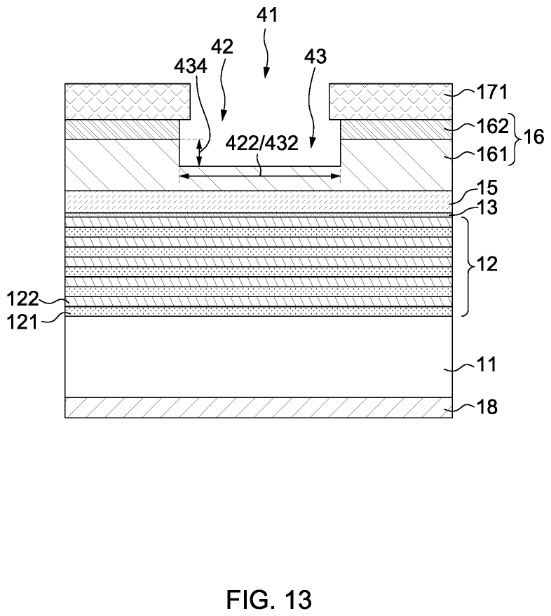

FIGS. 1 to 12 are cross-sectional views of intermediate stages of a method of manufacturing a photomask 100 shown in FIG. 13, in accordance with some embodiments of the present disclosure. It should be understood that additional operations can be provided before, during, and after the processes shown in FIGS. 1 to 13, and some of the operations described below can be replaced or eliminated for additional embodiments of the method. The order of the operations/processes may be changed. Materials, configurations, dimensions, processes and/or operations same as or similar to those described with respect to the foregoing embodiments may be employed in the following embodiments and the detailed explanation thereof may be omitted.

Referring to FIG. 1, a substrate 11 is provided, formed, or received. The substrate 11 may be formed of a low thermal expansion (LTE) material, such as fused silica, fused quartz, silicon, silicon carbide, black diamond or another low thermal expansion substance. In some embodiments, the substrate 11 serves to reduce image distortion resulting from mask heating. In the present embodiment, the substrate 11 includes material properties of a low defect level and a smooth surface. In some embodiments, the substrate 11 transmits light within a predetermined spectrum, such as visible wavelengths, infrared wavelengths near the visible spectrum (near-infrared), and ultraviolet wavelengths. In some embodiments, the substrate 11 absorbs EUV wavelengths and DUV wavelengths.

In some embodiments, a conductive layer 18 is disposed on a backside 11B of the substrate 11. The conductive layer 18 may aid in engaging the photomask 100 with an electric chucking mechanism (not separately shown) in a lithography system. In some embodiments, the conductive layer 18 includes chromium nitride (CrN), chromium oxynitride (CrON), or another suitable conductive material. In some embodiments, the conductive layer 18 includes a thickness in a range from about 20 nm to about 100 nm. The conductive layer 18 may be formed by CVD, ALD, molecular beam epitaxy (MBE), PVD, pulsed laser deposition, electron-beam evaporation, ion beam assisted evaporation, or any other suitable film-forming method.

In some embodiments, the conductive layer 18 has a surface area substantially equal to a surface area of the substrate 11. In some embodiments, an entirety of the conductive layer 18 is covered by the substrate 11. In some embodiments, the conductive layer 18 has a surface area less than a surface area of the substrate 11 (not shown). In an embodiment, an etching operation is formed to remove a peripheral portion of the conductive layer 18 so that an indentation of the conductive layer 18 with respect to the substrate 11 is formed. In some embodiments, the conductive layer 18 has a length or a width in a range between 70% and 95% of a length or a width, respectively, of the substrate 11.

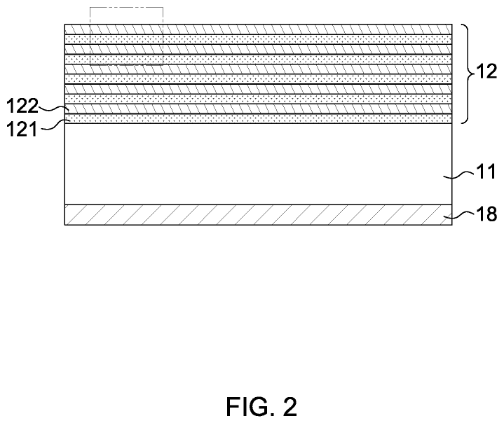

Referring to FIG. 2, a multilayer structure 12 is formed over a front side 11A of the substrate 11. The multilayer structure 12 serves as a radiation-reflective layer of the photomask 100. The multilayer structure 12 includes a plurality of molybdenum (Mo) layers 121 and a plurality of silicon layers 122 alternately arranged over the substrate 11. In other words, the multilayer structure 12 includes repeated units of layers, wherein each unit is formed of a Mo layer 121 and a Si layer 122. The number of alternating Mo layers 121 and Si layers 122 (i.e., the number of Mo/Si units) and the thicknesses of the Mo layers 121 and the Si layers 122 are determined so as to facilitate constructive interference of individual reflected rays (i.e., Bragg reflection) and thus increase the reflectivity of the multilayer structure 12.

In some embodiments, the reflectivity of the multilayer structure 12 is greater than about 60% for wavelengths of interest e.g., 13.5 nm. In some embodiments, the number of Mo/Si units in the multilayer structure 12 is between about 20 and about 80, e.g., 40. Further, in some embodiments, each of the Mo layers 121 or each of the Si layers 122 has a thickness between about 2 nm and about 10 nm. In some embodiments, the Mo layers 121 and the Si layers 122 have substantially equal thicknesses. In alternative embodiments, the Si layers 122 and the Mo layers 121 have different thicknesses. In some embodiments, a thickness of each of the Mo layers 121 is substantially greater than a thickness of each of the Si layers 122, e.g. by 1 nm. The Si layers 122 and the Mo layers 121 may be formed by physical vapor deposition (PVD), chemical vapor deposition (CVD), plasma-enhanced CVD (PECVD), atomic layer deposition (ALD), or any other suitable process.

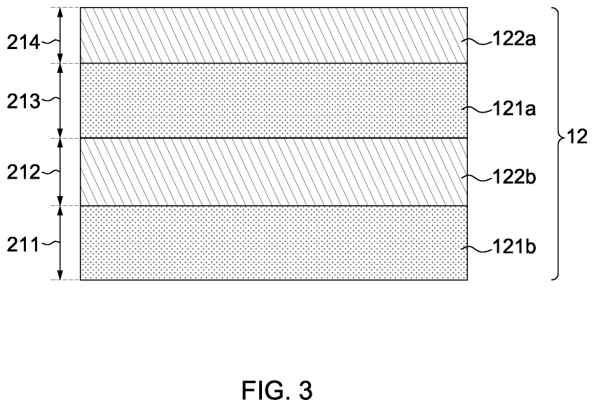

Referring to FIG. 3, an enlarged view of a portion of the multilayer structure 12 (indicated in FIG. 2 by a dashed line) is shown. For a purpose of illustration, the letters a, b, c, . . . etc. after the numbers 121 and 122 represent different units of the multilayer structure 12 from a top of the multilayer structure 12 toward the substrate 11. For instance, a Si layer 122a is a topmost layer of the Si layers 122 of the multilayer structure 12, and a Mo layer 121a disposed under the Si layer 122a is a topmost layer of the Mo layers 121 of the multilayer structure 12. A Si layer 122b and a Mo layer 122b represent a first Si layer below the Si layer 122a and a first Mo layer below the Mo layer 122a respectively. For ease of illustration and understanding, in the following description, the Si layer 122b can represent each of all other Si layers 122 of the multilayer structure 12. Similarly, the Mo layer 121b can represent each of all other Mo layers 121 below the topmost Mo layer 121a of the multilayer structure 12.

In some embodiments, the Mo layers 121a and 121b have substantially equal thicknesses (i.e., thicknesses 211 and 213 are substantially equal). In some embodiments, the thickness 211 or 213 is in a range of 3 to 5 nanometers (nm). In some embodiments, the thickness 211 of the Mo layer 121b is substantially greater than a thickness 212 of the Si layer 122b. In some embodiments, the thickness 212 of the Si layer 122b is in a range of 2 to 4 nm. A thickness 214 of the topmost Si layer 122a may be substantially equal to or less than the thickness 212 of the Si layer 122b. In some embodiments, the thickness 214 of the topmost Si layer 122a is less than the thickness 212 of the Si layer 122b as shown in FIG. 3. Each of all other Si layers 122 below the topmost Si layer 122a may have substantially equal thicknesses. In other words, in some embodiments, the thickness 214 of the topmost Si layer 122a is less than a thickness of each of the other Si layers 122 of the multilayer structure 12. In some embodiments, the thickness 214 of the topmost Si layer 122a is 50% to 90% of the thickness 212 of the Si layer 122b. In other words, the thickness 214 of the topmost Si layer 122a may be 10% to 50% less than the thickness 212 of the Si layer 122b. In some embodiments, the thickness 214 of the topmost Si layer 122a is about ¼ to about ⅓ of the thickness 212 of the Si layer 122b. In other words, the thickness 214 of the topmost Si layer 122a is about ⅔ to ¾ less than the thickness 212 of the Si layer 122b.

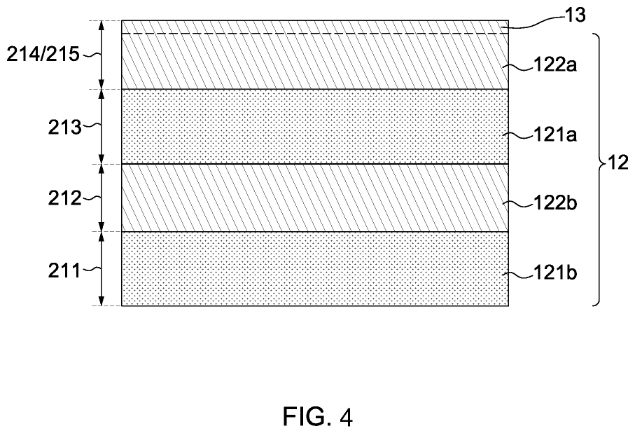

Referring to FIG. 4, an anti-oxidation layer 13 is formed over the topmost Si layer 122a. A material of the anti-oxidation layer 13 has a refractive index substantially equal to or very close to a refractive index of the topmost Si layer 122a. In some embodiments, a difference between the refractive index of the anti-oxidation layer 13 and the refractive index of the topmost Si layer 122a is less than 0.05. Materials of the anti-oxidation layer may be free of oxides. In some embodiments, the anti-oxidation layer 13 includes nitride, e.g., silicon nitride (SiₓN_{y}). In some embodiments, the anti-oxidation layer 13 includes trisilicon tetranitride (Si₃N₄). For a purpose of reflection, a total thickness 215 of the anti-oxidation layer 13 and the topmost Si layer 122a is controlled to be substantially equal to the thickness 212 of the Si layer 122b. In some embodiments, a thickness 216 of the anti-oxidation layer 13 is in a range of 0.3 to 1 nm. In some embodiments, the thickness 216 of the anti-oxidation layer 13 is about 10% to about 35% of the thickness 212. The anti-oxidation layer 13 may be formed by physical vapor deposition (PVD), chemical vapor deposition (CVD), plasma-enhanced CVD (PECVD), atomic layer deposition (ALD), or any other suitable process.

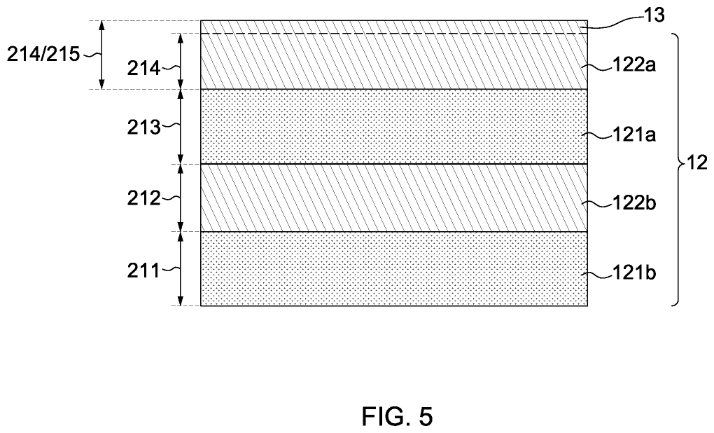

In alternative embodiments, the anti-oxidation layer 13 is formed at a surficial portion of the topmost Si layer 122a. As shown in FIG. 5, a nitridation is performed on the topmost Si layer 122a to transfer the surficial portion of the topmost Si layer 122a to a silicon nitride layer as the anti-oxidation layer 13. As described above, in some embodiments, the thickness 214 of the topmost Si layer 122a is substantially equal to the thickness 212 of the Si layer 122b. In such embodiments, for a purpose of reflection, no extra layer should be formed over the topmost Si layer 122a, and the nitridation is performed instead of deposition so as to keep the total thickness 215 substantially equal to the thickness 212.

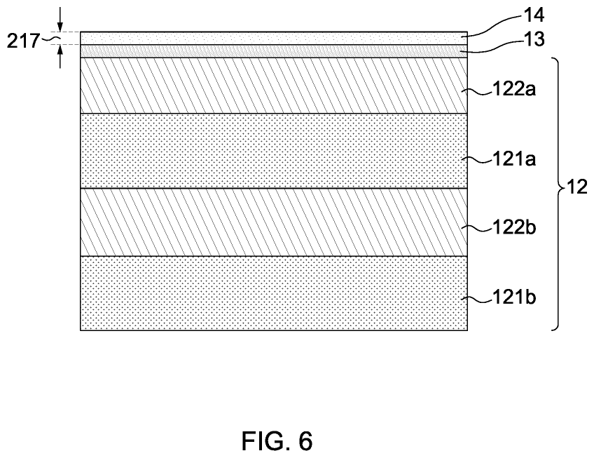

Referring to FIG. 6, an oxide-containing layer 14 may be formed over the anti-oxidation layer 13. In some embodiments, the oxide-containing layer 14 is for a purpose of optimizing a reflective efficiency of the multilayer structure 12. The oxide-containing layer 14 may be formed by physical vapor deposition (PVD), chemical vapor deposition (CVD), plasma-enhanced CVD (PECVD), atomic layer deposition (ALD), or any other suitable process. In some embodiments, a thickness 217 of the oxide-containing layer 14 is substantially equal to the thickness 216 of the anti-oxidation layer 13 shown in FIG. 4. In some embodiments, a thickness 217 of the oxide-containing layer 14 is in a range of 0.1 to 1 nm. FIG. 6 shows the oxide-containing layer 14 formed over the anti-oxidation layer 13 for a purpose of illustration. In some embodiments, the oxide-containing layer 14 is formed over the topmost Si layer 122a after the nitridation as shown in FIG. 5. In alternative embodiments, the oxide-containing layer 14 can be formed prior to the formation of the anti-oxidation layer 13.

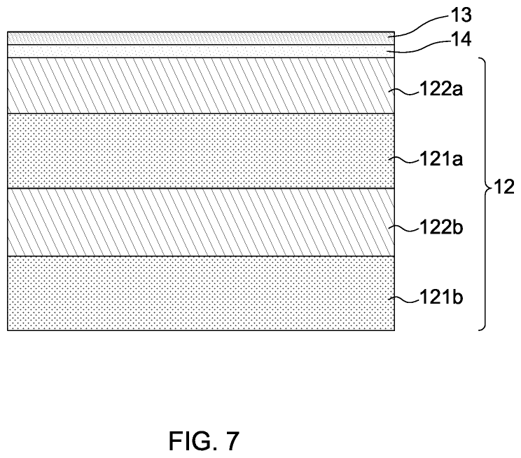

Referring to FIG. 7, the oxide-containing layer 14 is formed over the topmost Si layer 122a prior to the formation of the anti-oxidation layer 13 in accordance with some embodiments. In some embodiments, the oxide-containing layer 14 is formed between the anti-oxidation layer 13 and the topmost Si layer 122a. In some embodiments, the oxide-containing layer 14 contacts the topmost Si layer 122a. In some embodiments, the oxide-containing layer 14 is considered as a topmost layer of the multilayer structure 12.

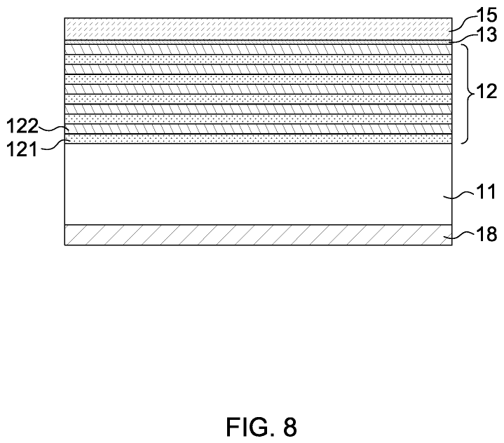

Referring to FIG. 8, a capping layer 15 is disposed over the multilayer structure 12. In some embodiments, the capping layer 15 is used to prevent oxidation of the multilayer structure 12 during a mask patterning process. In some embodiments, the capping layer 15 is a ruthenium-based layer. In some embodiments, the capping layer 15 is made of ruthenium (Ru) or ruthenium oxide (RuO₂). Other capping layer materials, such as silicon dioxide (SiO₂), amorphous carbon or other suitable compositions, can also be used in the capping layer 15. The capping layer 15 may have a thickness between about 1 nm and about 10 nm. In certain embodiments, the thickness of the capping layer 15 is between about 2 nm and about 4 nm. In some embodiments, the capping layer 15 is formed by PVD, CVD, low-temperature CVD (LTCVD), ALD or any other suitable film-forming method. In some embodiments, the capping layer 15 contacts the anti-oxidation layer 13.

In some embodiments as shown in FIG. 8, the capping layer 15 is formed on the anti-oxidation layer 13. In alternative embodiments having a nitridation performed on the topmost Si layer 122a as shown in FIG. 5, the capping layer 15 is formed on the topmost Si layer 122a. In some embodiments having the oxide-containing layer 14 over the anti-oxidation layer 13, the capping layer 15 is formed on the oxide-containing layer 14. In other embodiments having the oxide-containing layer 14 between the anti-oxidation layer 13 and the multilayer structure 12, the capping layer 15 is formed on the anti-oxidation layer 13 and separated from the oxide-containing layer 14.

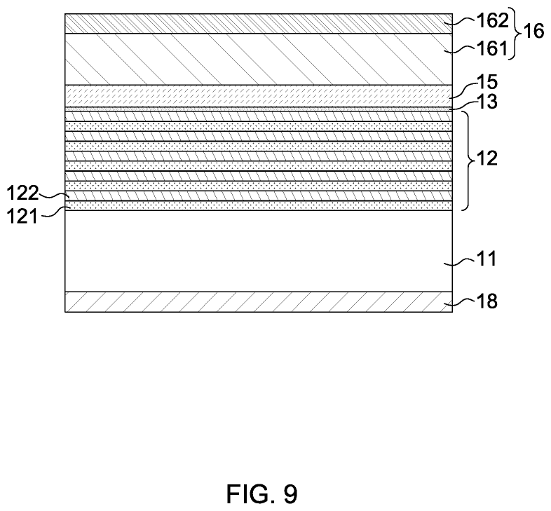

Referring to FIG. 9, a light-absorbing structure 16 is formed and disposed over the capping layer 15. In some embodiments, the light-absorbing structure 16 is an anti-reflective layer that absorbs radiation in the EUV wavelength ranges impinging on the photomask 100. The light-absorbing structure 16 may include chromium (Cr), chromium oxide (CrO), titanium nitride (TiO), tantalum nitride (TaN), tantalum oxide (TaO), tantalum boron (TaB), tantalum boron nitride (TaBN), tantalum boron oxide (TaBO), tantalum (Ta), titanium (Ti), aluminum-copper (Al—Cu), combinations thereof, or the like. The light-absorbing layer 16 may be formed of a single layer or of multiple layers. For example, the light-absorbing structure 16 may include a first absorbing layer 161 and a second absorbing layer 162. In some embodiments, the first absorbing layer 161 is formed over the capping layer 15, and the second absorbing layer 162 is formed over the first absorbing layer 161. In some embodiments, both the first absorbing layer 161 and the second absorbing layer 162 include Ta. In some embodiments, the first absorbing layer 161 includes TaBN and the second absorbing layer 162 includes TaBO. In some embodiments, the light-absorbing structure 16 has a thickness in a range between about 10 nm and about 100 nm, or between 40 nm and about 80 nm, e.g., 70 nm. In some embodiments, a thickness of the first absorbing layer 161 is greater than a thickness of the second absorbing layer 162. In some embodiments, the thickness of the first absorbing layer 161 is in a range of 5 to 70 nm. In some embodiments, the thickness of the second absorbing layer 162 is in a range of 5 to 20 nm. In some embodiments, each of the layers of the light-absorbing structure 16 is formed by PVD, CVD, LTCVD, ALD or any other suitable film-forming method.

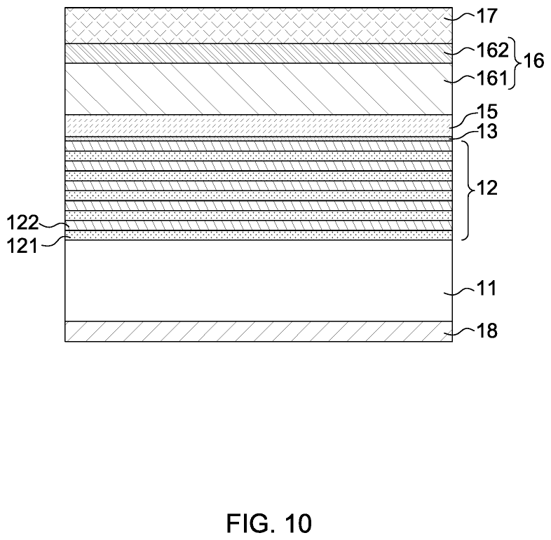

Referring to FIG. 10, a hard mask layer 17 is formed and disposed over the light-absorbing structure 16. In some embodiments, the hard mask layer 17 may be made of silicon, a silicon-based compound, chromium, a chromium-based compound, other suitable materials, or a combination thereof. In some embodiments, the chromium-based compound includes chromium oxide, chromium nitride, chromium oxynitride, or the like. In some embodiments, the hard mask layer 17 has a thickness between about 4 nm and about 20 nm.

In some embodiments, an antireflective layer (not shown) is disposed between the light-absorbing structure 16 and the hard mask layer 17. The antireflective layer may reduce reflection, from the light-absorbing structure 16, of the impinging radiation having a wavelength shorter than the DUV range. The antireflective layer may include Cr₂O₃, ITO, SiN, TaO₅, other suitable materials, or a combination thereof. In other embodiments, a silicon oxide film having a thickness between about 2 nm and about 10 nm is adopted as the antireflective layer. In some embodiments, the antireflective layer is formed by PVD, CVD, LTCVD, ALD, or any other suitable film-forming method.

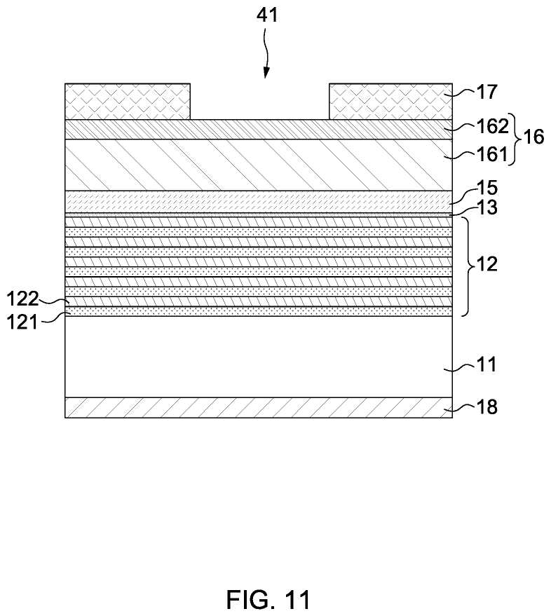

Referring to FIG. 11, the hard mask layer 17 is patterned to form a patterned mask layer 171 having an opening 41. Prior to the patterning of the hard mask layer 17, a photoresist layer may be deposited over the hard mask layer 17. The photoresist layer may be formed of a photosensitive material or other suitable resist materials. The photoresist layer may be deposited over the hard mask layer 17 by CVD, ALD, PVD, spin coating, or another suitable film-forming method. Once formed, the photoresist layer is patterned according to a predetermined circuit pattern. The patterning of the photoresist layer may include a mask-less exposure such as electron-beam writing, ion-beam writing, developing the photoresist layer and etching unwanted portions of the photoresist layer. The photoresist layer having an opening corresponding to the opening 41 is formed. The patterning of the hard mask layer 17 is then performed using the photoresist layer as a mask.

The patterning of the hard mask layer 17 may include performing photolithography and etching steps on the hard mask layer 17 to form the opening 41 penetrating completely through the hard mask layer 17. The opening 41 is formed as downward extensions of the opening of the photoresist layer. The opening 41 penetrates completely through the hard mask layer 17 and exposes the light-absorbing structure 16. An exemplary patterning process includes a first etching operation performed on the hard mask layer 17 using the photoresist layer as a mask. In some embodiments, the etching operation stops at an exposure of the light-absorbing structure 16. In some embodiments, the first etching operation is a dry etching operation and includes a directional dry etching or an anisotropic dry etching. A portion of the light-absorbing structure 16 is thereby exposed.

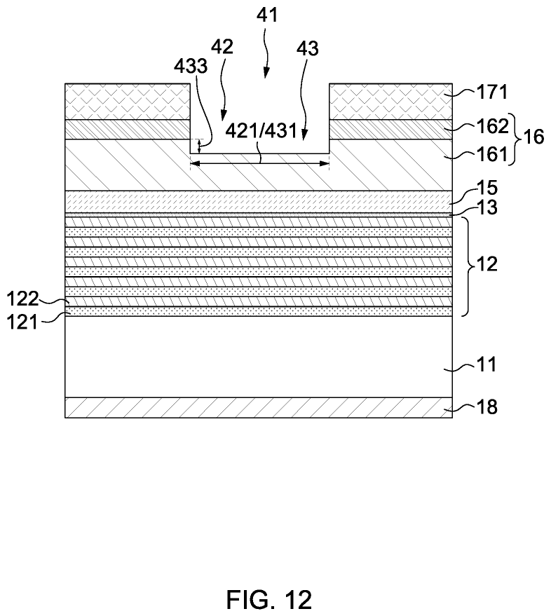

Referring to FIG. 12, a second etching operation is performed to remove a portion of the light-absorbing structure 16 exposed through the patterned mask layer 171. The second etching operation removes a portion of the second absorbing layer 162, and an opening 42 is thereby formed. The opening 42 is surrounded by and defined by the second absorbing layer 162. In some embodiments, the opening 42 penetrates completely through the second absorbing layer 162. The opening 42 is formed as a downward extension of the opening 41 and exposes the first absorbing layer 161. In some embodiments as shown FIG. 12, the second etching operation further removes a surficial portion of an exposed portion of the first absorbing layer 161. An opening 43 extending downward from the opening 42 is formed without penetrating completely through the first absorbing layer 161. The opening 43 has a depth 433 from a top surface of the first absorbing layer 161 less than the thickness of the first absorbing layer 161. In some embodiments, the second etching operation is a dry etching operation and includes a directional etching or an anisotropic etching, and sidewalls of the openings 41, 42 and 43 are substantially aligned or coplanar. In some embodiments, a width 421 of the opening 42 and a width 431 of the opening 43 are substantially equal.

Referring to FIG. 13, a third etching operation is performed for a purpose of control of critical dimensions (CD). In some embodiments, the third etching operation is a dry etching operation and includes an isotropic etching. The third etching operation is performed on the light-absorbing structure 16 in the openings 42 and 43. In some embodiments, the openings 42 and 43 are enlarged by the third etching operation. In some embodiments, a width 422 of the opening 42 after the third etching operation is greater than the width 421 in FIG. 12 prior to the third etching operation. In some embodiments, a width 432 of the opening 43 after the third etching operation is greater than the width 431 in FIG. 12 prior to the third etching operation. In some embodiments, a depth 434 of the opening 43 after the third etching operation is greater than the depth 433 prior to the third etching operation. The widths 422 and 432 of the openings 42 and 43 are according to patterns to be formed on a wafer or a substrate, and are not limited herein. An extent of the enlargement of the openings 42 and 43 can be controlled by a duration of the third etching operation. The duration of the third etching operation is controlled to achieve the predetermined widths 422 and 432 of the openings 42 and 43.

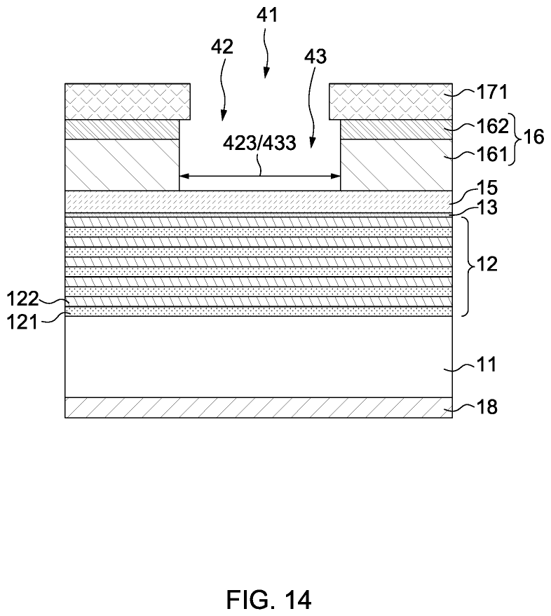

Referring to FIG. 14, a fourth etching operation is performed on the light-absorbing structure 16. In some embodiments, the fourth etching operation is a dry etching operation and includes a directional etching or an anisotropic etching. In some embodiments, a portion of the first absorbing layer 161 exposed in the opening 43 is removed by the fourth etching operation. In some embodiments, the fourth etching operation stops at an exposure of the capping layer 15. In some embodiments, the opening 43 becomes a through hole penetrating completely through the first absorbing layer 161. In some embodiments, a width 423 of the opening 42 after the fourth etching operation is substantially equal to the width 422 in FIG. 13. In some embodiments, a width 433 of the opening 43 after the fourth etching operation is substantially equal to the width 432 in FIG. 13.

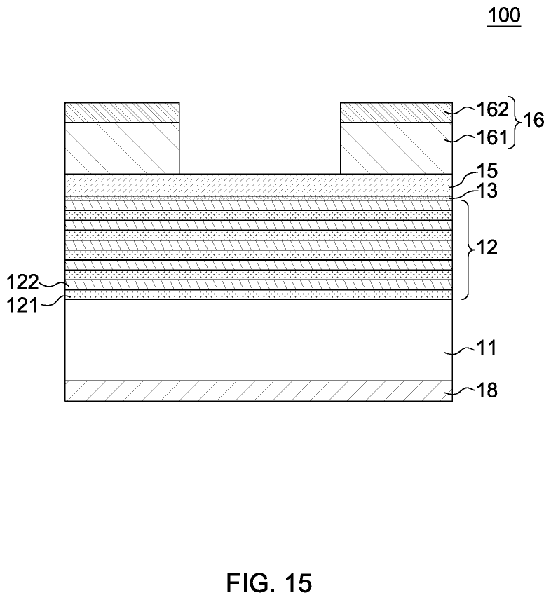

Referring to FIG. 15, the patterned mask layer 171 is removed, and the photomask 100 is formed. The removal of the patterned mask layer 171 may include an etching or an ashing operation. In some embodiments as shown in FIG. 15, the photomask 100 includes one anti-oxidation layer 13 disposed over the multilayer structure 12. In alternative embodiments, the multilayer structure 12 may include one or multiple layers functioning as an anti-oxidation layer.

For a purpose of brevity, only differences from other embodiments are emphasized in the following specification, and descriptions of similar or same elements, functions and properties are omitted. For a purpose of clarity and simplicity, reference numbers of elements with same or similar functions are repeated in different embodiments. However, such usage is not intended to limit the present disclosure to specific embodiments or specific elements. In addition, conditions or parameters illustrated in different embodiments can be combined or modified to have different combinations of embodiments as long as the parameters or conditions used are not in conflict.

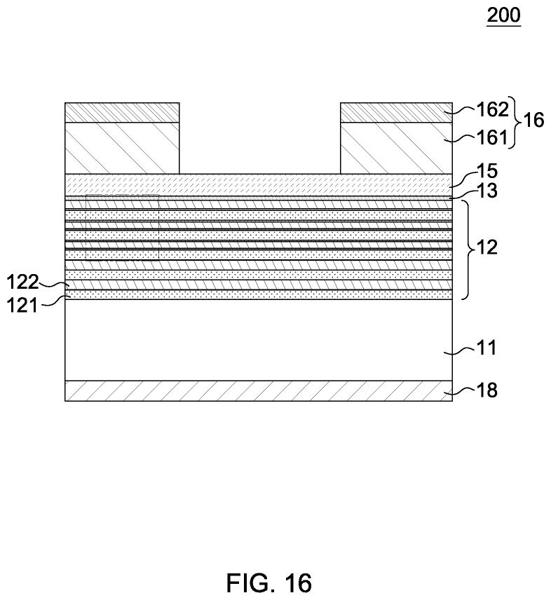

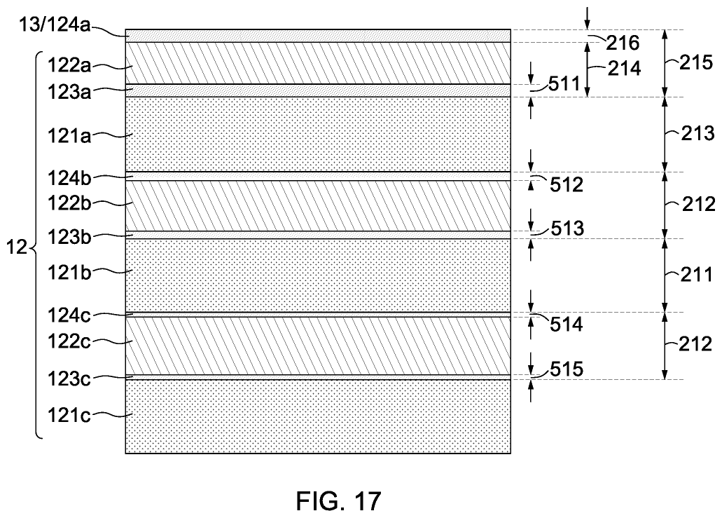

Referring to FIGS. 16 and 17, a photomask 200 similar to the photomask 100 is provided, wherein FIG. 16 is a schematic cross-sectional diagram of the photomask 200, and FIG. 17 is an enlarged view of a portion of the photomask 200 indicated by dashed lines in FIG. 16. In addition to the Mo/Si, a multilayer structure 12 of the photomask 200 further includes a first nitride layer 123 and a second nitride layer 124 repeatedly arranged on and under some of the Si layers 122. In addition to the formation of the anti-oxidation layer 13 as depicted in FIG. 4 or 5, operations similar to those of FIG. 4 or 5 can be performed prior to and/or after formation of some Si layers 122 to form the first nitride layer 123 and/or the second nitride layer 124.

Research has shown that oxidation or degradation is more likely to occur on the Si layers proximal to the capping layer 15. For a purpose of anti-oxidation, a Si layer 122 proximal to the capping layer 15 is separated by the first nitride layer 123 and the second nitride layer 124 from adjacent Mo layers 121. A pair of a first nitride layer 123 and a second nitride layer 124 may contact a same Si layer 122. For instance as shown in FIG. 17, a first nitride layer 123a is disposed under and contacts the topmost Si layer 122a; a second nitride layer 124b is disposed on and contacts the Si layer 122b; a first nitride layer 123b is disposed under and contacts the Si layer 122b; a second nitride layer 124c is disposed on and contacts the Si layer 122c; and a first nitride layer 123c is disposed under and contacts the Si layer 122c.

In some embodiments, a pair of a first nitride layer 123 and a second nitride layer 124 contacting a same Si layer 122 may have substantially equal thicknesses. In some embodiments, the anti-oxidation layer 13 is referred to as a second nitride layer 124a contacting the topmost Si layer 122a, and a thickness 511 of the first nitride layer 123a is substantially equal to a thickness 216 of the second nitride layer 124a. In some embodiments, a thickness 512 of the second nitride layer 124b is substantially equal to a thickness 513 of the first nitride layer 123b. In some embodiments, a thickness 514 of the second nitride layer 124c is substantially equal to a thickness 515 of the first nitride layer 123c.

Similar to the above illustration, for a purpose of reflection, a total thickness of a Si layer and the adjacent pair of nitride layers 123 and 124 should be controlled substantially to the thickness 212 of the Si layer 122b as depicted in FIG. 4. In addition, because the extent of oxidation of the Si layers 122 decreases as a distance to a top surface of the multilayer structure 12 increases, a thickness of each of the pair of nitride layers 123 and 124 may decrease as the distance to the top surface of the multilayer structure 12 increases. For example, as shown in FIG. 17, the thickness 216 or the thickness 511 may be greater than the thickness 512 or the thickness 513, and the thickness 512 or the thickness 513 may be greater than the thickness 514 or the thickness 515. In some embodiments, the nitride layers 123 and 124 include only a few pairs at a few Si layers 122 proximal to the top surface of the multilayer structure 12 since no oxidation is observed, e.g., below the Si layer 122c. In some embodiments, a thickness of the topmost Si layer 122a is substantially less than a thickness of the Si layer 122b. In some embodiments, a thickness of the Si layer 122b is substantially less than a thickness of the Si layer 122c.

In alternative embodiments, the nitridation as depicted in FIG. 5 is performed instead of the deposition to form the first nitride layer 123 and/or the second nitride layer 124. In such embodiments, a thickness of each of the Si layers 122 may be substantially equal to the thickness 212 as depicted in FIG. 3. In some embodiments, the nitridation is performed after deposition of each of a few Si layers (e.g., 122a, 122b and 122c) proximal to the top surface of the multilayer structure 12 to form the second nitride layers (e.g., 124b and 124c). In some embodiments, the nitridation is further performed on a few Mo layers (e.g., 121a, 121b and 121c) 121 prior to the deposition of each of a few Si layers (e.g., 122a, 122b and 122c) proximal to the top surface of the multilayer structure 12 to form the first nitride layers (e.g., 123a, 123b and 123c). The anti-oxidation layer 13 or the second nitride layer 124a can be formed by deposition or nitridation, wherein the method of formation of the anti-oxidation layer 13 or the second nitride layer 124a can be same as or different from the method of formation of the first nitride layer 123 and/or the second nitride layer 124. In addition, the anti-oxidation layer 13 or the second nitride layer 124a can have thicknesses that are same as, or different from, the thicknesses of the first nitride layer 123 and/or the second nitride layer 124.

It should be noted that a position and a number of the first nitride layers 123, the second nitride layers 124 and the anti-oxidation layer 13 are provided for a purpose of illustration. The position and the number of the first nitride layers 123, the second nitride layers 124 or the anti-oxidation layer 13 can be adjusted according to different applications. In some embodiments, only the anti-oxidation layer 13 is formed as shown in FIG. 15. In some embodiments, only the first nitride layer(s) 123 and the anti-oxidation layer 13 are formed. In some embodiments, only the second nitride layer(s) 124 and the anti-oxidation layer 13 are formed.

The present disclosure provides a photomask and a method of manufacturing the photomask. Researchers have observed that top Si layers of a multilayer structure, especially a topmost Si layer which is also a topmost layer of the multilayer structure, may oxidize during repeated exposure to EUV radiation. In the proposed photomask, an anti-oxidation layer is formed at least on the topmost Si layer of the multilayer structure of the photomask and serves to reduce or eliminate the effect of oxidation of the layers of the photomask. The service life and operation cycles of the photomask are thereby improved.

To conclude the operations as illustrated in FIGS. 1 to 17 above, a method 600 and a method 700 within a same concept of the present disclosure are provided.

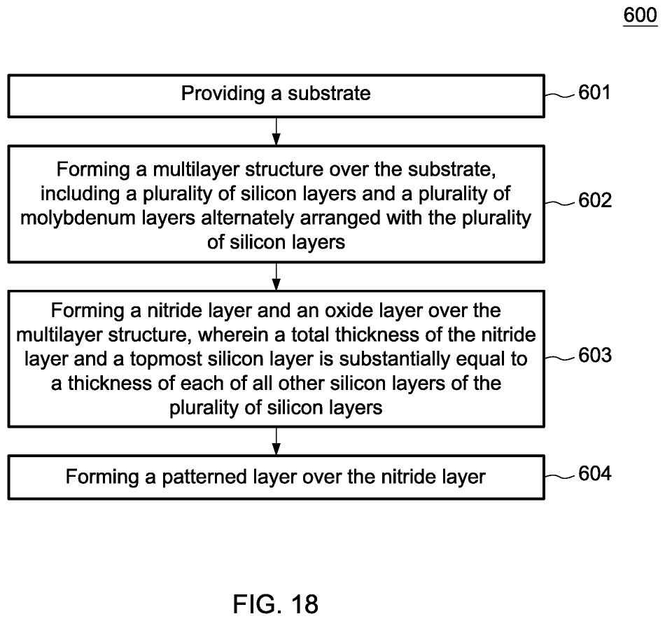

FIG. 18 is a flow diagram of a method 600 for manufacturing a semiconductor structure in accordance with some embodiments of the present disclosure. The method 600 includes a number of operations (601, 602, 603, and 604) and the description and illustration are not deemed as a limitation to the sequence of the operations. A substrate is provided, received or formed in the operation 601. A multilayer structure is formed over the substrate in the operation 602, wherein the multilayer structure includes a plurality of silicon layers and a plurality of molybdenum layers alternately arranged with the plurality of silicon layers. A nitride layer and an oxide layer are formed over the multilayer structure in the operation 603, wherein a total thickness of the nitride layer and a topmost silicon layer is substantially equal to a thickness of each of all other silicon layers of the plurality of silicon layers. A patterned layer is formed over the nitride layer in the operation 604.

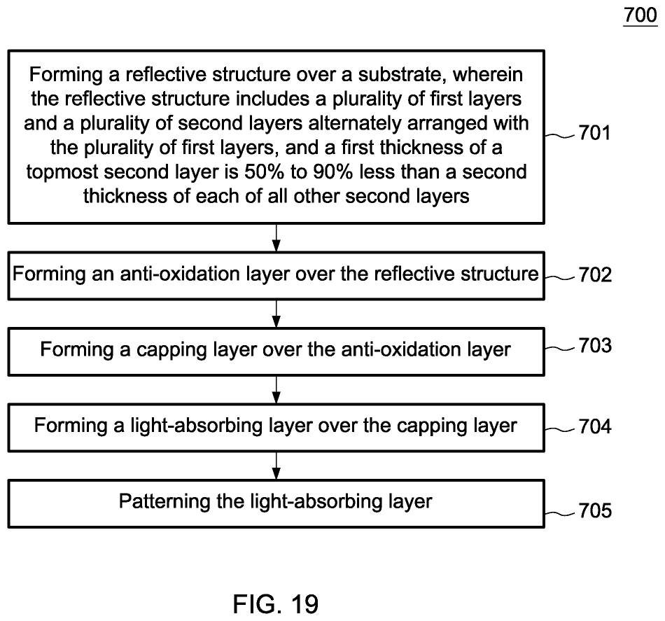

FIG. 19 is a flow diagram of a method 700 for manufacturing a semiconductor structure in accordance with some embodiments of the present disclosure. The method 700 includes a number of operations (701, 702, 703, 704 and 705) and the description and illustration are not deemed as a limitation to the sequence of the operations. A reflective structure is formed over a substrate in the operation 701, wherein the reflective structure includes a plurality of first layers and a plurality of second layers alternately arranged with the plurality of first layers, and a first thickness of a topmost second layer is 50% to 90% less than a second thickness of each of all other second layers. An anti-oxidation layer is formed over the reflective structure in the operation 702. A capping layer is formed over the anti-oxidation layer in the operation 703. A light-absorbing layer is formed over the capping layer in the operation 704 and patterned in the operation 705. It should be noted that the operations of the method 600 and/or the method 700 may be rearranged or otherwise modified within the scope of the various aspects. Additional processes may be provided before, during, and after the method 600 and/or the method 700, and some other processes may be only briefly described herein. Thus, other implementations are possible within the scope of the various aspects described herein.

In accordance with some embodiments of the disclosure, a method for manufacturing a photomask structure is provided. The method may include several operations. A substrate is provided, received or formed. A multilayer structure is formed over the substrate, wherein the multilayer structure includes a plurality of silicon layers and a plurality of molybdenum layers alternately arranged with the plurality of silicon layers. A nitride layer and an oxide layer are formed over the multilayer structure, wherein a total thickness of the nitride layer and a topmost silicon layer is substantially equal to a thickness of each of all other silicon layers of the plurality of silicon layers. A patterned layer is formed over the nitride layer.

In accordance with some embodiments of the disclosure, a method for manufacturing a photomask structure is provided. The method may include several operations. A reflective structure is formed over a substrate, wherein the reflective structure includes a plurality of first layers and a plurality of second layers alternately arranged with the plurality of first layers, and a first thickness of a topmost second layer is 50% to 90% less than a second thickness of each of all other second layers. An anti-oxidation layer is formed over the reflective structure. A capping layer is formed over the anti-oxidation layer. A light-absorbing layer is formed over the capping layer. The light-absorbing layer is then patterned.

In accordance with some embodiments of the disclosure, a photomask structure is provided. The photomask structure includes a substrate, a multilayer structure, an oxide layer, an anti-oxidation layer, a ruthenium-based layer, and a light-absorbing layer. The multilayer structure is disposed over the substrate and includes a plurality of silicon layers and a plurality of molybdenum layers alternately arranged with the plurality of silicon layers, wherein a thickness of a topmost silicon layer is 10% to 50% less than a thickness of each of all other silicon layers of the plurality of silicon layers. The oxide layer is disposed over the multilayer structure. The anti-oxidation layer is disposed over the oxide layer. The ruthenium-based layer is disposed over the anti-oxidation layer. The light-absorbing layer is disposed over the ruthenium-based layer.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of manufacturing a photomask, comprising:
providing a substrate;
forming a multilayer structure over the substrate, including a plurality of silicon layers and a plurality of molybdenum layers alternately arranged with the plurality of silicon layers;
forming a nitride layer and an oxide layer over the multilayer structure, wherein a total thickness of the nitride layer and a topmost silicon layer is substantially equal to a thickness of each of all other silicon layers of the plurality of silicon layers; and
forming a patterned layer over the nitride layer.

2. The method of claim 1, wherein the forming the multilayer structure includes:
depositing a first molybdenum layer over the substrate;
depositing a first silicon layer over the first molybdenum layer;
depositing a topmost molybdenum layer over the first silicon layer; and
depositing the topmost silicon layer over the topmost molybdenum layer.

3. The method of claim 1, wherein a thickness of the topmost silicon layer is 50% to 90% of a thickness of each of all other silicon layers of the plurality of silicon layers.

4. The method of claim 1, wherein the forming of the nitride layer includes:
depositing a silicon nitride layer over the topmost silicon layer.

5. The method of claim 1, wherein the forming of the nitride layer includes:
performing a nitridation to transfer a surficial portion of the topmost silicon layer to a silicon nitride layer.

6. The method of claim 1, wherein the forming of the oxide layer is performed prior to the forming of the nitride layer.

7. The method of claim 1, wherein the forming of the nitride layer is performed prior to the forming of the oxide layer.

8. A method of manufacturing a photomask, comprising:
forming a reflective structure over a substrate, wherein the reflective structure includes a plurality of first layers and a plurality of second layers alternately arranged with the plurality of first layers, and a first thickness of a topmost second layer is 50% to 90% less than a second thickness of each of all other second layers;
forming an anti-oxidation layer over the reflective structure;
forming a capping layer over the anti-oxidation layer;
forming a light-absorbing layer over the capping layer; and
patterning the light-absorbing layer.

9. The method of claim 8, wherein a third thickness of the anti-oxidation layer is in a range of 0.3 to 1 nanometer.

10. The method of claim 8, wherein a total thickness of a third thickness of the anti-oxidation layer and the first thickness is substantially equal to the second thickness.

11. The method of claim 10, wherein the third thickness is about 10% to about 35% of the second thickness.

12. The method of claim 8, wherein the second thickness is in a range of 2 to 4 nanometers.

13. The method of claim 8, wherein the reflective structure further includes a plurality of third layers, and all of the third layers contact the second layer.

14. The method of claim 13, wherein a total thickness of a first layer and two adjacent third layers is in a range of 2 to 4 nanometers.

15. The method of claim 13, further comprising:
forming a hard mask layer prior to the patterning of the light-absorbing layer; and
patterning the hard mask layer concurrently with the patterning of the light-absorbing layer.

16. A structure of a photomask, comprising:
a substrate;
a multilayer structure, disposed over the substrate and including a plurality of silicon layers and a plurality of molybdenum layers alternately arranged with the plurality of silicon layers, wherein a thickness of a topmost silicon layer is 10% to 50% less than a thickness of each of all other silicon layers of the plurality of silicon layers;
an oxide layer, disposed over the multilayer structure;
an anti-oxidation layer, disposed over the oxide layer;
a ruthenium-based layer, disposed over the anti-oxidation layer; and
a light-absorbing layer, disposed over the ruthenium-based layer.

17. The structure of claim 16, further comprising:
a conductive layer, disposed at a side of substrate opposite to the multilayer structure.

18. The structure of claim 16, wherein the anti-oxidation layer includes silicon nitride.

19. The structure of claim 16, wherein the anti-oxidation layer contacts the oxide layer.

20. The structure of claim 16, wherein a thickness of the oxide layer is in a range of 0.1 to 1 nanometer.
